(19) United States
(12) Patent Application Publication
(10) Pub. No.: US 2008/0122472 A1
(43) Pub. Date: May 29, 2008

(54) Testing jig of electronic signal

(76) Inventor: Shu-Hua Chen, Zhonghe City (TW)

Correspondence Address: TROXELL LAW OFFICE PLLC, 5205 LEESBURG PIKE, SUITE 1404, FALLS CHURCH, VA, 22041, US

(21) Appl. No.: 11/522,371

(22) Filed: Sep. 18, 2006

(51) Int. Cl. G01R 31/26

(52) U.S. Cl. 324/765

(57) ABSTRACT

A testing jig of electronic signal is disclosed. The testing jig of electronic signal capable of providing electrical connection between a plurality of contact pads of the circuit board and a plurality of ball-shaped leads of the ball-grid-array packaging device in order to perform testing with respect to the ball-grid-array packaging device includes a connecting interface and at least a conducting gel. The connecting interface has a plurality of guiding connecting devices, each of them is one-to-one correspondent to the plurality of contact pads wherein each of the guiding connecting devices is aligned with and electrically connected to the contact pad. The conducting gel has a first side surface and a second side surface. The first side surface being bonded to the connecting interface is connected to the other end of the guiding connecting devices while the second side surface is bonded and connected to the plurality of ball-shaped leads. The conducting gel having a plurality of conducting wires makes the first side surface and the second side surface perform electrical connection.

### BACKGROUND OF THE INVENTION

1. Field of the Invention

The invention relates to a testing jig of the electronic signal, and more particularly, to a testing jig of the electronic signal for performing testing with respect to the packaging device of a ball grid array.

2. Description of the Prior Art

The ball grid array packaging IC (integrated circuit) has become the mainstream of the packaging device of the semiconductor device nowadays. This is because that it has a relatively high I/O (input/output) density. Besides, it can directly dispose on the circuit board by utilizing the SMT (surface mounting technology). In general, all the semiconductor packaging chips need to go through a specific package testing process. However, since the ball-grid-array packaging device has a relatively higher I/O density and special ball-shaped leads, the testing method is relatively difficult and different from those of the other semiconductor packaging devices. The test socket assembly of the ball-grid-array packaging device is mainly utilized to make the ball-shaped leads of the ball-grid-array packaging device contact with the contact area of the circuit board. In this way, the ball-shaped leads of the ball-grid-array packaging device is capable of achieving the testing objective without being directly bonded to the contact area of the circuit board.

FIG. 1 is a structural and cross-sectional view of the conventional ball grid array socket assembly used for connecting the ball-shaped leads of the ball-grid-array packaging device and the via hole of the circuit board. As shown in FIG. 1, the conventional BGA (ball grid array) testing socket assembly (1) includes a case (10) and a fixture (11) wherein the case (10) has a inter-face layer (101) and a containing space (102). The inter-face layer (101) has a plurality of via holes (103) for containing a plurality of resilient guiding pins (104). The containing space (102) is capable of containing ball-grid-array packaging device (12). The ball-grid-array packaging device (12), after being placed in the containing space (102), is clamped by the fixture (11) to make the ball-shaped leads (120) contact with a corresponding contact end (104a) of the resilient guiding pins (104). The other contact end, i.e. the leads (104b), being extended out of the case (10) is capable of making contact with the a plurality of guiding holes (130) of the circuit board (13) of the non-real system, and is employed to perform the testing of the ball-grid-array packaging device (12). However, since the conventional ball grid array testing socket assembly (1) needs to have its leads (104b) insert in the corresponding guiding holes (130) of the circuit board (13) for performing testing, one not only needs to utilize a specialized circuit board (33) (i.e. a circuit board (13) of a non-real system) made for testing that causes the increase of the cost, the process of inserting the leads (104b) in the guiding holes (130) is apt to damage the leads (104b) that causes the testing error as well. What is more, following the development of the trend of minimized and highly integrated semiconductor packaging device, the lead density of the semiconductor packaging device is higher than ever. Accordingly, the pitch of the leads is getting smaller and smaller, thereby, the pitch of the guiding connection area of the testing circuit board is getting smaller and smaller too. Therefore, the cost of the testing circuit board specially made will increase, and the testing error caused by the damaging leads (104b) due to the inserting process will be getting worse. Moreover, since the transmission speed of the electronic device is higher than ever, the conventional method of hole-inserting and the contact structure of resilient guiding pins (104) will cause excessive electrical impedance that consequently makes it unable to be utilized in a high speed testing structure. Accordingly, the design of the layout of high-speed testing circuit board is getting more and more difficult following the higher-than-ever transmission speed.

FIG. 2 is a structural and cross-sectional view of another conventional ball grid array socket assembly used for connecting the ball-shaped leads of the ball-grid-array packaging device and the via hole of the circuit board. The ball grid array socket assembly is a U.S. Patent published (announced in public) on December 30 of 1997 titled as “BALL GRID ARRAY SOCKET ASSEMBLY” that discloses another ball grid array socket structure and testing method. As shown in FIG. 2, the ball grid array socket assembly (2) includes a case (20) and a fixture (21). The case (20) further includes a interface layer (201) and a containing space (202). The interface layer (201) having a plurality of via holes (203) is capable of containing a plurality of resilient conductive pins (204) while the containing space (202) is capable of containing the ball-grid-array packaging device (22). After being placed in the containing space (202), the ball-grid-array packaging device (22) is capable of being clamped by the fixture (21) so that the ball-shaped leads (220) of the ball-grid-array packaging device (22) is capable of making contact with a contact end (240a) of the corresponding resilient guiding pins (204). The other contact end of the resilient guiding pins (204) forms a ball-shaped leads (204b) that is extended from the case (20) for performing testing with respect to the ball-grid-array packaging device (22).

However, since the other end of the resilient guiding pins (204) needs the planting of the ball-shaped leads (204b), not only the working process of the resilient guiding pins (204b) is tedious, but the process of assembling the resilient guiding pins (204b) on the socket assembly (2) is also time consuming and inconvenient and apt to cause the problem of being not good in contact. Moreover, the socket assembly (2) of the prior art is not advantageous on the disposition and performance of a plurality of socket assemblies (2) since when it comes to disposing a plurality of socket assemblies (2) on a circuit board (23), each of the socket assembly (2) needs to align with the contact area of the circuit board (23).

In addition, following the highly developed semiconductor industry, the dimension and the packaging configuration of the integrated circuit device will change in compliance with the standards and demands. In response to the market demands, the configuration and dimension of the positioning seat of the socket assembly have to change accordingly in association with the semiconductor-packaging device to be tested. However, the positioning seat of the conventional socket assembly is normally not able to be displaced and is fixed in dimension and configuration, whenever there is a semiconductor packaging device having different specification needed to be tested, making a new socket assembly is necessary. This is not only wasting cost and time-consuming but also slowing down the testing process.

Therefore, just how to develop a kind of testing method and socket assembly of the ball-grid-array packaging device to improve the above-mentioned disadvantages of the prior art has become an urgent issue nowadays.

### SUMMARY OF THE INVENTION

In light of the disadvantages of the prior arts, the invention provides a multi-function probe card that aims to ameliorate at least some of the disadvantages of the prior art or to provide a useful alternative.

The primary objective of the invention is to provide a testing jig of the electronic signal that directly disposes at least a conducting gel by the use of ball-grid-array packaging device to perform electronic signal testing with respect to the real circuit board to achieve the efficacy of diminishing the time for circuit testing and lowering the cost.

It is another objective of the invention to provide a testing jig of the electronic signal that disposes a connecting interface between the circuit board and ball-grid-array packaging device to make the ball-grid-array packaging device perform testing on the circuit board of the real system so as to facilitate the disposition of a number of socket assemblies and improvement of testing efficiency.

To attain the above-mentioned objectives, the invention provides a testing jig of electronic signal that is capable of providing electrical connection between a plurality of contact pads of the circuit board and a plurality of ball-shaped leads of the ball-grid-array packaging device in order to perform testing with respect to the ball-grid-array packaging device. The testing jig of the electronic signal includes a connecting interface and at least a conducting gel. The connecting interface has a plurality of guiding connecting devices, each of them is one-to-one correspondent to the plurality of contact pads wherein each of the guiding connecting device is aligned with and electrically connected to the contact pad. The conducting gel has a first side surface and a second side surface. The first side surface being bonded to connecting interface is connected to the other end of the guiding connecting devices while the second side surface is bonded and connected to the plurality of ball-shaped leads. The conducting gel having a plurality of conducting wires has the first side surface and the second side surface perform electrical connection.

### BRIEF DESCRIPTION OF THE DRAWINGS

The accomplishment of this and other objectives of the invention will become apparent from following description and its accompanying drawings of which:

FIG. 1 is a structural and cross-sectional view of the conventional ball grid array socket assembly used for connecting the ball-shaped leads of the ball-grid-array packaging device and the via hole of the circuit board;

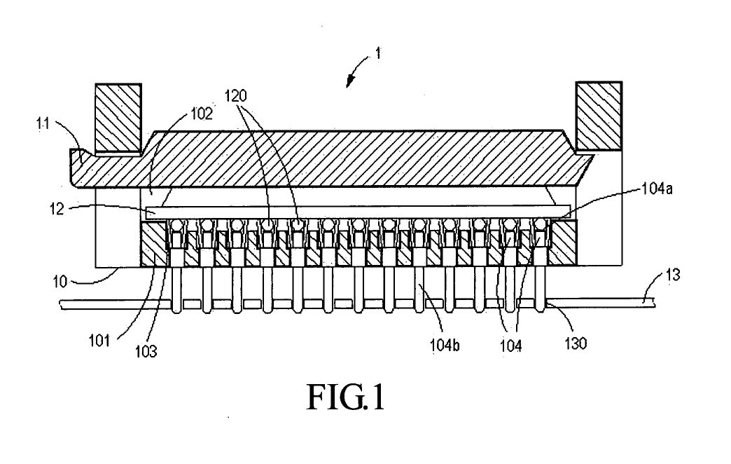

FIG. 2 is a structural and cross-sectional view of another conventional ball grid array socket assembly used for connecting the ball-shaped leads of the ball-grid-array packaging device and the via hole of the circuit board;

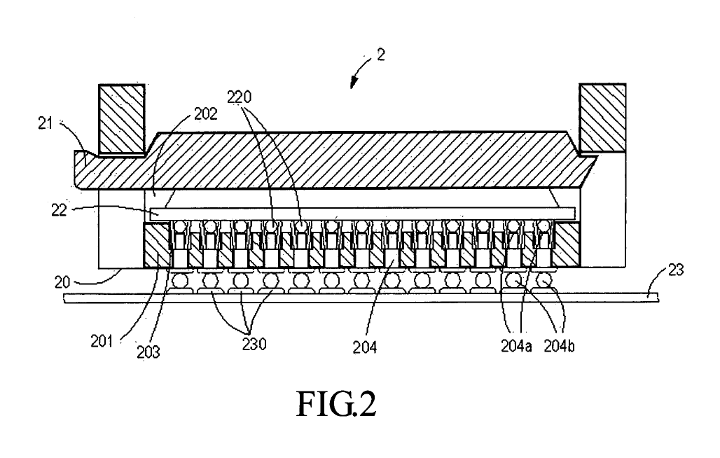

FIG. 3 is an isometric exploded view of the testing jig of the electronic signal of the preferred embodiment of the invention;

FIG. 4 is an isometric exploded view of the testing jig of the electronic signal used for connecting the ball-grid-array packaging device and the circuit board of the preferred embodiment of the invention;

FIG. 5 is a structural and cross-sectional view of the testing jig of the electronic signal used for connecting the ball-grid-array packaging device and the circuit board of the preferred embodiment of the invention.

### DETAILED DESCRIPTION OF THE PREFERRED EMBODIMENT

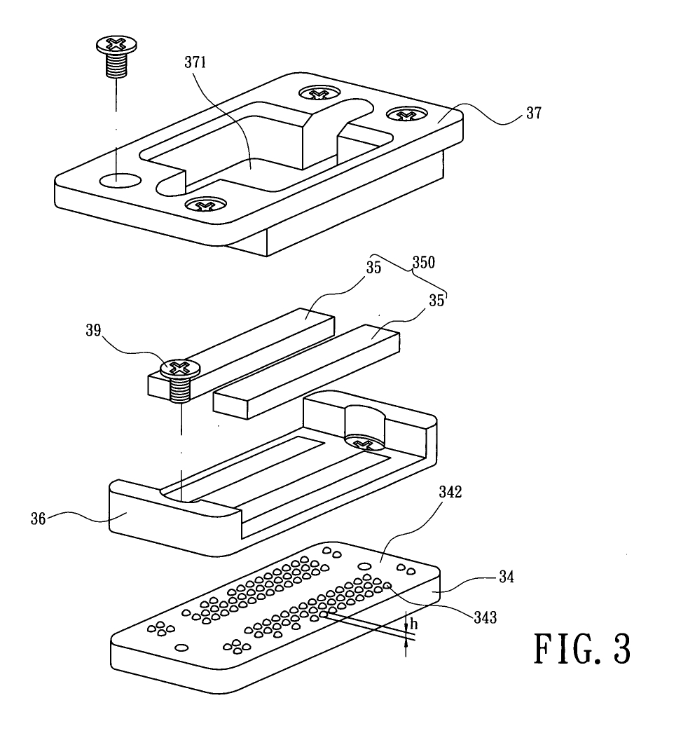

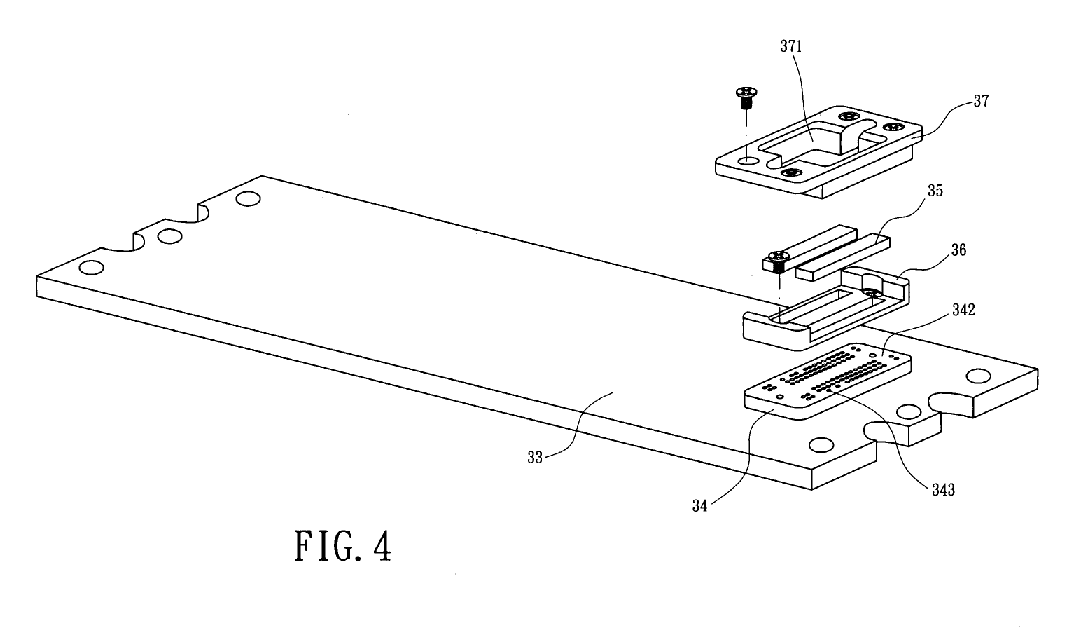

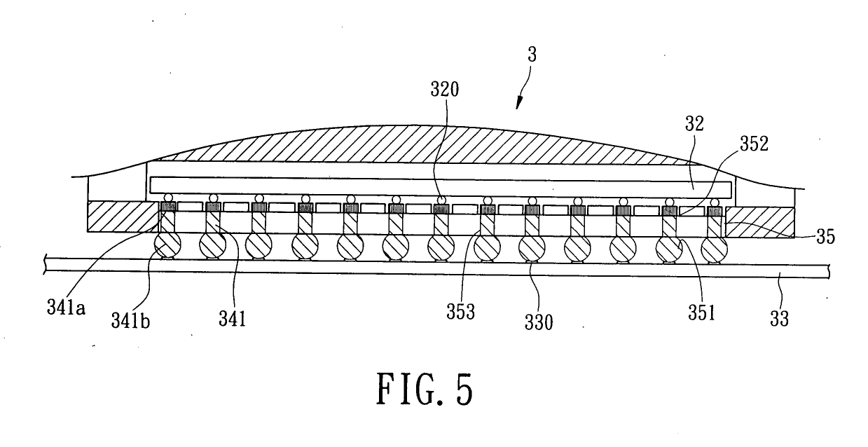

FIG. 3 is an isometric exploded view of the testing jig of the electronic signal of the preferred embodiment of the invention; FIG. 4 is an isometric exploded view of the testing jig of the electronic signal used for connecting the ball-grid-array packaging device and the circuit board of the preferred embodiment of the invention; while FIG. 5 is a structural and cross-sectional view of the testing jig of the electronic signal used for connecting the ball-grid-array packaging device and the circuit board of the preferred embodiment of the invention. As shown in FIG. 3, FIG. 4 and FIG. 5, the testing jig (3) of the electronic signal of the invention is capable of performing testing on the circuit board (33) of the real system with respect to the ball-grid-array packaging device (32). The testing jig (3) of the electronic signal mainly makes use of a plurality of guiding connecting devices (341) of a connecting interface (34) in association with at least a conducting gel (35) to connect to the ball-shaped leads (320) of the ball-grid-array packaging device (32) and the contact pad (330) of the circuit board (33). The conductive connecting device (341) has a first end (341a) and a second end (341b). In this way, the testing jig (3) of the electronic signal is capable of performing the testing with respect to the ball-grid-array packaging device (32) on the circuit board (33) of the real system.

At first, the preferred embodiment of the invention provides a real system circuit board (33) having a plurality of contact pads (330). The testing jig (3) of the electronic signal is then employed to perform aligned connecting testing. The testing jig (3) of the electronic signal of the invention includes a connecting interface (34) and a conducting portion (350). The connecting interface (34) has a plurality of guiding connecting devices (341) and a top surface (342). The conducting portion (350) being at least a conducting gel (35) includes a first side surface (351) and a second side surface (352). The first end (341a) of each of the guiding connecting devices (341) is electrically connected the first side surface (351) of the conducting gel (35) while the second end (341b) of the guiding connecting devices (341) is contacted to the corresponding contact pad (330) on the circuit board (33). The top surface (342) of the connecting interface (34) further includes a plurality of transferring ports (343) protruding a height “h” upright on the top surface (342), thereby the conducting gel (35) is capable of positively rest on the plurality of transferring ports (343). Afterwards, the ball-grid-array packaging device (32) is provided to make the ball-shaped leads (320) thereof contact the second side surface (352) of the conducting gel (35). The conducting gel (35) has a plurality of conducting wires (353) that are connected to the first side surface (351) at a predetermined angle θ. Besides, the conducting wires (353) being electroplated by either silver or gold material makes the first side surface (351) electrically connect to the second side surface (352). The testing jig (3) of the electronic signal of the invention thus performs testing with respect to the ball-grid-array packaging device (32) based on the above-mentioned process.

The chip-testing module applicable to the conception of the invention can be either a single-chip testing module constituted by a single testing jig (3) of electronic signal or a multi-chip testing module constituted by a plurality of testing jigs (3) of electronic signal. In the preferred embodiment of the invention, the testing jig (3) of the electronic signal further includes a bearing seat (36), a securing portion (39), and a positioning seat (37). The connecting interface (34) being provided between the conducting gel (35) and the circuit board (33) is used as a signal transmission medium between the conducting gel (35) and the circuit board (33). The connecting interface (34) has a plurality of via holes (not shown in the Figure), each of the via hole forms the conductive connecting device (341) with its first end (341a) and its second end (341b) exposing to the upper and lower surfaces respectively. The guiding connecting devices (341) are preferably made of but not limited to tin or copper. The first end (341a) of the guiding connecting devices (341) makes contact with the corresponding the first side surface (351) of the conducting gel (35). Since the first end (341a) of the guiding connecting devices (341) is capable of providing a contact area relatively larger that that of the contact pad (330) of the circuit board (33), hence a relatively better contact can be achieved between the conducting gel (35) and the connecting interface (34). Besides, as the second end (341b) of the guiding connecting devices (341) is a ball-shaped lead, the second end (341b) of the guiding connecting devices (341) is capable of connecting to the corresponding contact pad (330) of the circuit board (33) by the use of surface mounting technology (SMT) after the assembling work of the testing socket set is completed. Therefore, the invention is capable of performing the testing of ball-grid-array packaging device on the circuit board (33) of the real system.

When it comes to performing testing with respect to the ball-grid-array packaging device (32), it is necessary to use the positioning seat (37) to make the ball-shaped leads (320) of the ball-grid-array packaging device contact with the corresponding conducting gel (35). Therefore, the positioning seat (37) has a containing space (371) for containing the ball-grid-array packaging device (32). In some of the embodiments, the positioning seat (37) is secured with the bearing seat (36) and the connecting interface (34) by the use of the securing portion (39) such as a screw. When it comes to testing a device having different shape and size of package as well as different number of the ball-shaped lead, one can use a tool to loose the securing portion (39) so as to change the positioning seat (37) with containing space (371) having different shape and size. In this way, the invention is capable of meeting the different demands to resolve the disadvantage of the prior art that the testing jig (3) of the electronic signal needs to make a new mold since the positioning seat (37) is unable to be changed. In some other embodiments, a bearing seat (36) is further designed to contain the conducting gel (35) in order to make the conducting gel (35) positively connect to the connecting interface (34) and positioning seat (37). Certainly, the chip-testing module applicable to the conception of the invention can be either a single-chip testing module constituted by a single testing jig (3) of electronic signal or a multi-chip testing module constituted by a plurality of testing jigs (3) of electronic signal. When the chip-testing module is a multi-chip testing module constituted by a plurality of testing jigs (3) of electronic signal, the bearing seat (36), securing portion (39), and the positioning seat (37) etc. can all be selectively shared to facilitate the assembling work and economize the cost.

To summarize the above-mentioned statements, as the testing jig of the electronic signal of the invention is used as the transmission medium of electronic signal between the circuit board and the ball-grid-array packaging device by the use of connecting interface and conducting gel, thereby, one needs only the circuit board of the real system without the necessity of making another testing circuit board of electronic signal resulting the increase of cost. In addition, the testing jig (3) of the electronic signal utilizes positioning seat of the disassembling type, all one has to do is to loose the securing portion (39), and the positioning seat (37) can be elastically changed to increase the application elasticity and save the time of making another mold. What is more, as the testing jig (3) of the electronic signal makes use of the guiding connecting devices (341) of the connecting interface (34), it is capable of providing a relatively larger contact area to makes contact with the conducting gel (35), thereby, the invention is capable of improving the quality of signal transmission and the electrical mechanism.

It will become apparent to those people skilled in the art that various modifications and variations can be made to the structure of the invention without departing from the scope or spirit of the invention. In view of the foregoing description, it is intended that all the modifications and variation fall within the scope of the following appended claims and their equivalents.

What is claimed is:

1. A testing jig of the electronic signal for providing electrical connection with respect to a plurality of contact pads on a circuit board and a plurality of ball-shaped leads of a ball-grid-array packaging device to perform testing with respect to the ball-grid-array packaging device, the testing jig of the electronic signal comprising:
a connecting interface having a plurality of guiding connecting devices and each of the guiding connecting devices is one-to-one correspondent to and electrically connected to and aligned with the contact pad; and
at least a conducting gel having a first side surface and a second side surface, the first side surface being bonded to the connecting interface is connected to the other end of the guiding connecting devices while the second side surface is bonded and connected to the plurality of ball-shaped leads; the conducting gel having a plurality of conducting wires makes the first side surface and the second side surface perform electrically connection.

2. The testing jig of the electronic signal as claimed in claim 1, wherein the conducting wires is electroplated by either silver or gold material.

3. The testing jig of the electronic signal as claimed in claim 1, wherein the conducting wires are connected to the first side surface at a predetermined angle.

4. The testing jig of the electronic signal as claimed in claim 1, wherein the ball-shaped leads of the guiding connecting devices are electrically connected to the contact pad.

5. The testing jig of the electronic signal as claimed in claim 1, wherein the guiding connecting devices are electrically connected to the contact pad by the use of the SMT (surface mounting technology).

6. The testing jig of the electronic signal as claimed in claim 1, wherein the guiding connecting device is made of Tin or Copper materials.

7. The testing jig of the electronic signal as claimed in claim 1 further includes a bearing seat for containing the conducting gel.

8. The testing jig of the electronic signal as claimed in claim 7 further includes a securing portion that is connected to the circuit board through the bearing seat and the connecting interface.

9. The testing jig of the electronic signal as claimed in claim 1 further includes a positioning seat for containing the ball-grid-array packaging device and making the plurality of ball-shaped leads of the ball-grid-array packaging device contact with the conducting gel.

10. A testing jig of the electronic signal for providing electrical connection with respect to a plurality of contact pads on a circuit board and a plurality of ball-shaped leads of a ball-grid-array packaging device to perform testing with respect to the ball-grid-array packaging device, the testing jig of the electronic signal comprising:
a connecting interface having a plurality of guiding connecting devices and each of the guiding connecting devices is one-to-one correspondent to and electrically connected to and aligned with the contact pad, a top surface of the connecting interface further having a plurality of transferring ports protruding a height upright on the top surface; and
a conducting portion having a first side surface and a second side surface, the first side surface being bonded to the plurality of transferring ports while the second side surface is bonded and connected to the plurality of ball-shaped leads; the conducting portion makes the first side surface and the second side surface perform electrically connection.

11. The testing jig of the electronic signal as claimed in claim 10, wherein the conducting portion is at least a conducting gel that has a plurality of conducting wires making the first side surface and the second side surface perform electrical connection.

12. The testing jig of the electronic signal as claimed in claim 11, wherein the conducting wires is electroplated by either silver or gold material.

13. The testing jig of the electronic signal as claimed in claim 11, wherein the conducting wires are connected to the first side surface at a predetermined angle.

14. The testing jig of the electronic signal as claimed in claim 10, wherein the ball-shaped leads of the guiding connecting devices are electrically connected to the contact pad.

15. The testing jig of the electronic signal as claimed in claim 10, wherein the guiding connecting devices are electrically connected to the contact pad by the use of the SMT (surface mounting technology).

16. The testing jig of the electronic signal as claimed in claim 10, wherein the guiding connecting device is made of Tin or Copper materials.
